(19) United States
(12) Patent Application Publication
(10) Pub. No.: US 2024/0274617 A1
(43) Pub. Date: Aug. 15, 2024

(54) DISPLAY PANEL, METHOD FOR MANUFACTURING THE SAME, DISPLAY SCREEN AND DISPLAY DEVICE

(71) Applicant: TIANMA ADVANCED DISPLAY TECHNOLOGY INSTITUTE (XIAMEN) CO., LTD., Xiamen (CN)

(72) Inventors: Zhibo YANG, Xiamen (CN); Yangui FENG, Xiamen (CN); Bo ZHOU, Xiamen (CN); Yuxiong CAI, Xiamen (CN)

(73) Assignee: TIANMA ADVANCED DISPLAY TECHNOLOGY INSTITUTE (XIAMEN) CO., LTD., Xiamen (CN)

(21) Appl. No.: 18/642,851

(22) Filed: Apr. 23, 2024

(30) Foreign Application Priority Data
Dec. 29, 2023 (CN) 202311867798.5

(51) Int. Cl. H01L 27/12

(52) U.S. Cl. CPC H01L 27/124; H01L 27/1288

(57) ABSTRACT

A display panel, a method for manufacturing the display panel, a display screen, and a display device are provided. The display panel includes a substrate and multiple first wires. The substrate includes a first surface and a second surface that are opposite. The first surface faces a display face of the display panel. The multiple first wires are arranged on a side of the first surface away from the second surface. The second surface includes a first division and a second division. A maximum distance between adjacent first wires in the first division is H₁, and a maximum distance between adjacent first wires in the second division is H₂. H₁ is greater than H₂. The distance between adjacent first wires in the first division is increased to be greater than the distance between adjacent first wires in the second division.

The present application claims priority to Chinese Patent Application No. 202311867798.5, titled “DISPLAY PANEL, METHOD FOR MANUFACTURING THE SAME, DISPLAY SCREEN AND DISPLAY DEVICE”, filed on Dec. 29, 2023 with the China National Intellectual Property Administration, which is incorporated herein by reference in its entirety.

### FIELD

The present disclosure relates to the field of displays, and in particular to a display panel, a method for manufacturing the display panel, a display screen, a display device and a tiled display apparatus.

### BACKGROUND

Seamless tiled displays using Micro LEDs depend on the technology of wiring on side/back surfaces. Wiring on the back surface is formed by photolithography or engraving. How to improve the reliability of wiring on the side/back surface is a problem to be solved urgently.

### SUMMARY

A display panel, a method for manufacturing the display panel, a display screen, a display device and a tiled display apparatus are provided according to the present disclosure, to solve a problem that proneness to detachment of a patterned dry film from the display panel during removal of a supporting film affects a product yield in related technology.

A display panel is provided in an aspect of the present disclosure. The display panel includes a substrate and multiple first wires. The substrate includes a first surface and a second surface that are opposite to each other. The first surface faces a display face of the display panel. The multiple first wires are arranged on a side of the first surface away from the second surface. The second surface includes a first division and a second division. A maximum distance between two adjacent first wires in the first division is H₁, and a maximum distance between two adjacent first wires in the second division is H₂. H₁ is greater than H₂. The distance between adjacent first wires in the first division is increased to be greater than the distance between adjacent first wires in the second division. In this way, an area of a patterned dry film that is formed by the first wires in the first division and attached to the display panel is increased, to reduce a risk of detachment of the patterned dry film during removal of a supporting film, to improve a product yield.

A method for manufacturing the display panel is provided in another aspect of the present disclosure. The method includes: providing a substrate, where the substrate has a first surface and a second surface that are opposite to each other, and the second surface includes a first division and a second division; and forming multiple first wires on the second surface, where a maximum distance between two adjacent first wires in the first division is H₁, a maximum distance between two adjacent first wires in the second division is H₂, and H₁ is greater than H₂. In the display panel manufactured with the method, the distance between adjacent first wires in the first division on the second surface is increased, to increase an area of a patterned dry film that is formed by the first wires in the first division and attached to the display panel, to reduce a risk of detachment of the patterned dry film during removal of a supporting film, to improve a product yield.

A display screen is further provided in another aspect of the present disclosure. The display screen includes the display panel described above or a display panel manufactured with the method described above. In the display screen, the distance between adjacent first wires in the first division is greater than the distance between adjacent first wires in the second division on the second surface of the display panel. In this way, an area of a patterned dry film that is formed by the first wires in the first division and attached to the display panel is increased, to reduce a risk of detachment of the patterned dry film during removal of a supporting film, to improve a yield of the display screen.

A display device is further provided in another aspect of the present disclosure. The display device includes the display screen described above. In the display device, the distance between adjacent first wires in the first division is greater than the distance between adjacent first wires in the second division on the second surface of the display panel of the display screen. In this way, an area of a patterned dry film that is formed by the first wires in the first division and attached to the display panel is increased, to reduce a risk of detachment of the patterned dry film during removal of a supporting film, to improve a yield of the display device.

A tiled display apparatus is further provided in another aspect of the present disclosure. The tiled display apparatus includes multiple of the display device described above. In the tiled display apparatus, the distance between adjacent first wires in the first division is greater than the distance between adjacent first wires in the second division on the second surface of the display panel of the display screen in each display device. In this way, an area of a patterned dry film that is formed by the first wires in the first division and attached to the display panel is increased, to reduce a risk of detachment of the patterned dry film during removal of a supporting film, to improve a yield of the tiled display apparatus.

The display panel according to the embodiments of the present disclosure includes an active area, a substrate and multiple first wires. The substrate includes a first surface and a second surface that are opposite to each other. The first surface faces a display face of the display panel. The multiple first wires are arranged on a side of the first surface away from the second surface. A maximum distance between two adjacent first wires in the first division is H₁, and a maximum distance between two adjacent first wires in the second division is H₂. H₁ is greater than H₂. The distance between adjacent first wires in the first division is increased to be greater than the distance between adjacent first wires in the second division. In this way, an area of a patterned dry film that is formed by the first wires in the first division and attached to the display panel is increased, to reduce a risk of detachment of the patterned dry film during removal of a supporting film, to improve a product yield.

### BRIEF DESCRIPTION OF THE DRAWINGS

The drawings constituting a part of the present disclosure are used to provide a further understanding of the present disclosure, and the exemplary embodiments and descriptions of the present disclosure are used to explain the present disclosure, and do not constitute an improper limitation to the present disclosure. In the drawings:

FIG. 1 is a top view of part of a second surface of a display panel according to an embodiment of the present disclosure;

FIG. 2 is a sectional view of part of the display panel according to an embodiment of the present disclosure;

FIG. 3 is a top view of part of the second surface of the display panel according to another embodiment of the present disclosure;

FIG. 4 is a top view of part of the second surface of the display panel according to another embodiment of the present disclosure;

FIG. 5 is a top view of part of the second surface of the display panel according to another embodiment of the present disclosure;

FIG. 6 is a top view of part of the second surface of the display panel according to another embodiment of the present disclosure;

FIG. 7 is a top view of part of the second surface of the display panel according to another embodiment of the present disclosure;

FIG. 8 is a top view of part of the second surface of the display panel according to another embodiment of the present disclosure;

FIG. 9 is a top view of part of the second surface of the display panel according to another embodiment of the present disclosure;

FIG. 10 is a top view of part of a side surface of the display panel according to an embodiment of the present disclosure;

FIG. 11 is a top view of part of spread back surface and side surface of the display panel illustrated in FIG. 1 and FIG. 10;

FIG. 12 is a top view of part of a back surface of a display panel according to another embodiment of the present disclosure;

FIG. 13 is a top view of part of a back surface of a display panel according to another embodiment of the present disclosure;

FIG. 14 is a flowchart of a method for manufacturing a display panel according to an embodiment of the present disclosure; and

FIG. 15 is a top view of part of wiring on the back surface of the display panel according to an embodiment of the present disclosure.

Reference numerals are listed as follows.

| | | | |
|---|---|---|---|
| 10 | substrate | | |
| 110 | first surface | 111 | light-emitting device |
| 112 | backlight layer | 113 | bonding layer |
| 114 | protective adhesive | 115 | connector |
| 101 | first division | 102 | second division |
| 103 | third division | 104 | fourth division |
| 120 | first wiring region | 130 | second wiring region |
| 140 | second surface | | |
| 150 | side surface | | |
| 20 | first wire | 201 | first interval |
| 202 | second interval | 203 | first segment |
| 204 | second segment | 205 | third segment |
| 30 | driver chip | 40 | second wire |
| 401 | third interval | 402 | fourth interval |
| 50 | dry film | | |

### DETAILED DESCRIPTION

It should be noted that the embodiments of the present disclosure and features in the embodiments can be combined with each other without conflict. The present disclosure is described in detail below in conjunction with the embodiments and with reference to the drawings.

The embodiments of the present disclosure are clearly and completely described hereinafter in conjunction with the drawings of the embodiments of the present disclosure. Apparently, the described embodiments are only some embodiments of the present disclosure, rather than all embodiments.

It should be noted that the terms “first”, “second” and the like in the specification, the claims and the drawings of the present disclosure are used to distinguish similar objects rather than to describe a particular sequence or order. It should be understood that the terms used in such a way are interchangeable in proper circumstances to describe the embodiments of the present disclosure. Moreover, the terms such as “include/comprise”, “have” or any other variants thereof are intended to be non-exclusive. For example, a process, method, system, product or device including a series of steps or elements includes not only the expressly listed steps or elements but also other steps or elements that are not enumerated or are inherent for the process, method, system, product or device.

As described in the Background, in the conventional technology, the display panels depend on wiring on side/back surfaces. Wiring on the back surface is implemented by photolithography or engraving. How to improve the reliability of wiring on the side/back surface is a problem to be solved urgently. A display panel, a method for manufacturing the display panel, a display screen, a display device and a tiled display apparatus are provided according to the embodiments of the present disclosure.

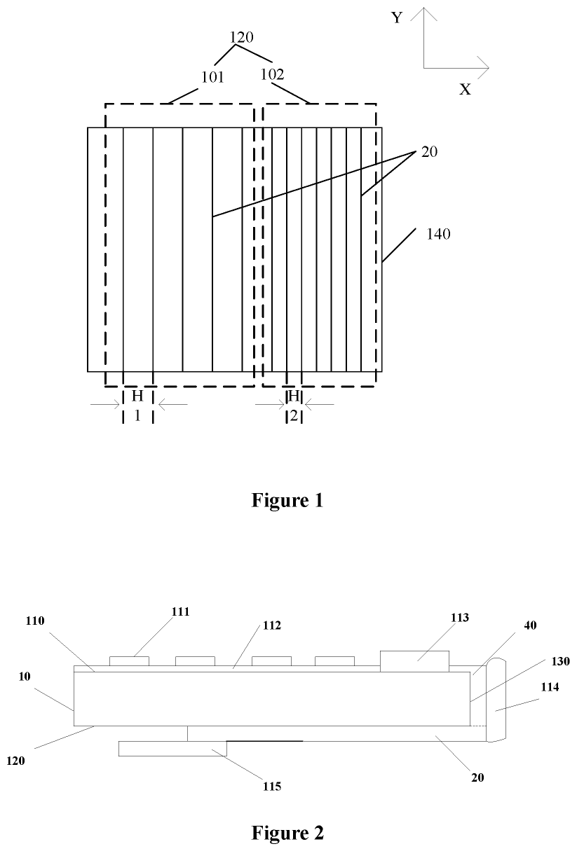

A display panel is provided according to an embodiment of the present disclosure. As illustrated in FIG. 1 and FIG. 2, the display panel includes a substrate 10 and multiple first wires 20. The substrate 10 has a first surface 110 and a second surface 140 that are opposite to each other. The first surface 110 faces a display face of the display panel. The first wires 20 are arranged on a side, of the first surface 110, away from the second surface 140. The second surface 140 includes a first division 101 and a second division 102. A maximum distance between two adjacent first wires 20 in the first division 101 is H₁, and a maximum distance between two adjacent first wires 20 in the second division 102 is H₂. H₁ is greater than H₂.

In the above embodiment, the second surface 140, of the substrate 10, away from the display face of the display panel includes the first division 101 and the second division 102. Regions of the first wires 20 are hollows formed by patterning a dry film. The distance between adjacent first wires 20 in the first division 101 is greater than the distance between adjacent first wires 20 in the second division 102 to increase an area of the patterned dry film that is formed by the first wires 20 in the first division 101 and attached to the display panel, to reduce a risk of detachment of the patterned dry film during removal of a supporting film, to improve a product yield.

Core principles of the present disclosure are described above. The embodiments of the present disclosure are clearly and completely described hereinafter in conjunction with the drawings in the embodiments of the present disclosure.

FIG. 1 is a top view of part of a second surface of a display panel. As illustrated in FIG. 1 and FIG. 2, the display panel according to an embodiment of the present disclosure includes the substrate 10 and the multiple first wires 20. The substrate 10 has the first surface 110 arranged close to the display face of the display panel. The substrate 10 further has the second surface 140 opposite to the first surface 110. As illustrated in FIG. 1, the second surface 140 includes the first division 101 and the second division 102. The distance between adjacent first wires 20 in the first division is H₁, and the distance between adjacent first wires in the second division 102 is H₂. H₁ is greater than H₂. Regions of the first wires 20 are hollows formed by patterning the dry film. In this way, the area of the patterned dry film that is formed by the first wires 20 in the first division 101 and attached to the display panel is increased, to reduce a risk of detachment of the patterned dry film during removal of a supporting film, to improve a product yield.

In the above embodiments, as illustrated in FIG. 1 and FIG. 2, the first surface 110 of the substrate 10 of the display panel may be provided with a backlight layer 112, a light-emitting device 111, and a bonding layer 113. The second surface 140 of the substrate 10 of the display panel may be provided with a connector 115. Functional layers can be arranged on the first surface 110 and the second surface 140 of the display panel properly according to actual situations, which is not limited in the present disclosure. In a case that another layer is arranged on the second surface 140, the first wires 20 on the second surface 140 are not in direct contact with the substrate.

In the above embodiments, other functional layers may be arranged on the first surface and the second surface of the substrate. Therefore, in the present disclosure, the first wires 20 may not be in direct contact with the substrate.

In some embodiments, as illustrated in FIG. 1 and FIG. 2, the multiple first wires are arranged along a first direction X and extend along a second direction Y. The second direction Y intersects with the first direction X.

In the above embodiments, as illustrated in FIG. 1 and FIG. 2, the first wires 20 on the second surface 140 of the substrate 10 of the display panel are arranged along the first direction X and extend along the second direction Y. The first direction X intersects with the second direction Y.

In some embodiments, as illustrated in FIG. 1 and FIG. 2, the multiple first wires are arranged along the first direction X, and the first division 101 and the second division 102 are arranged along the first direction.

In the above embodiments, as illustrated in FIG. 1 and FIG. 2, the first division 101 and the second division 102 on the second surface 140 of the substrate 10 are arranged along the first direction X, and the first wires 20 in the first division 101 and the first wires 20 in the second division 102 are arranged along the first direction X.

In some embodiments, as illustrated in FIG. 1 and FIG. 2, the second surface 140 includes a first wiring region 120. The first wiring region 120 includes the first division 101 and the second division 102. The first division 101 is arranged on a side, of the second division 102, close to an edge of the first wiring region 120.

In the above embodiments, as illustrated in FIG. 1 and FIG. 2, the second surface 140 of the substrate 10 includes the first wiring region 120. Both the first division 101 and the second division 102 are arranged within the first wiring region 120. The first division 101 is arranged close to an edge of the first wiring region 120, and the second division 102 is arranged close to a center of the first wiring region 120. By arranging the first division close the edge of the first wiring region 120 on the second surface 140, the distance between adjacent first wires 20 in the first division 101 is increased. Regions of the first wires 20 are hollows formed by patterning the dry film. In this way, and an area of intervals between adjacent first wires 20 is increased, to enhance adhesion of the dry film formed between adjacent hollows before removal of the dry film.

In some embodiments, as illustrated in FIG. 1, a distance between ends of the adjacent first wires 20 in the first division 101 is H₁.

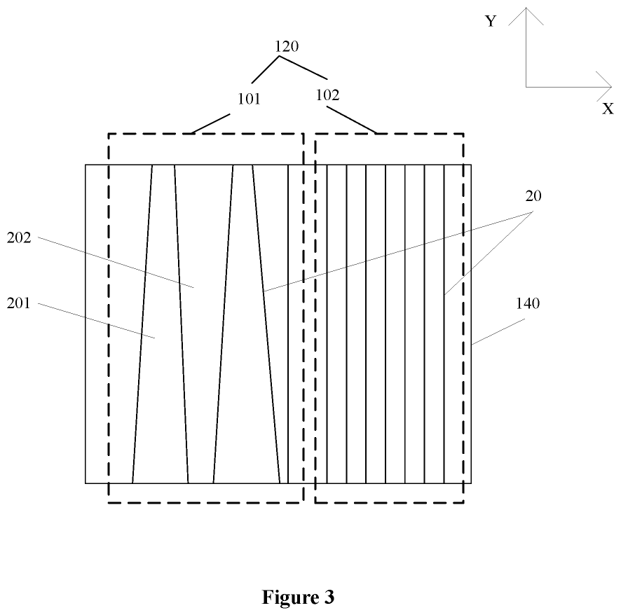

In some embodiments, as illustrated in FIG. 3, there is a first interval 201 or a second interval 202 between adjacent first wires 20 in the first division 101. The first interval 201 alternates with the second interval 202 in the first direction X. The first interval 201 tapers along the second direction, and the second interval 202 tapers against the second direction.

In the above embodiment, as illustrated in FIG. 3, the multiple first wires 20 in the first wiring region 120 on the second surface are arranged along the first direction X and extend along the second direction Y. The second direction Y intersects with the first direction X. The multiple first wires 20 are parallel to each other. There is the first interval 201 or the second interval 202 between adjacent first wires 20 in the first division 101. The first interval 201 alternates with the second interval 202 in the first direction X, and an average area of the first interval 201 and the second interval 202 is greater than an average area of intervals between adjacent first wires 20 in the second division 102. Regions of the first wires 20 are hollows formed by patterning the dry film, and the area of the patterned dry film that is formed by the first wires 20 in the first division 101 and attached to the display panel is increased, to reduce a risk of detachment of the patterned dry film during removal of the supporting film, to improve a product yield. By alternating the first interval 201 with the second interval 202, distances between the first wires 20 in the first division 101 are even, to enhance the reliability of the patterned dry film formed by the intervals between the first wires 20, to avoid damage to part of the dry film during removal of the dry film resulted from uneven adhesion of different parts of the dry film due to an excessive or insufficient interval between some of the first wires 20.

For example, as illustrated in FIG. 3, the multiple first wires 20 are arranged along the first direction X and extend along the second direction Y. The second direction Y intersects with the first direction X. There is the first interval 201 or the second interval 202 between adjacent first wires 20 in the first division 101. The first interval 201 alternates with the second interval 202 in the first direction X. The first interval 201 tapers along the second direction Y, and the second interval 202 tapers against the second direction Y.

In the above embodiments, as illustrated in FIG. 3, there is the first interval 201 or the second interval 202 between adjacent first wires 20 on the second surface 140 of the display panel. The first interval 201 tapers along the second direction Y, and the second interval 202 tapers against the second direction Y. The first interval 201 and the second interval 202 are arranged along the first direction X in the first division 101 to uniform an average width of a same interval. Regions of the first wires 20 are hollows formed by patterning the dry film. In this embodiment, the width of a same interval changes gradually along the second direction Y, and the first interval 201 alternates with the second interval 202, avoiding that the interval between adjacent first wires 20 occupies too much space at a same end of the second direction Y. The first interval 201 alternates with the second interval 202, and distances between first wires 20 in the first division 101 are even, to enhance the reliability of the patterned dry film formed by the first wires 20, to avoid damage to part of the dry film during removal of the dry film resulted from uneven adhesion of different parts of the dry film due to an excessive or insufficient interval between some of the first wires 20.

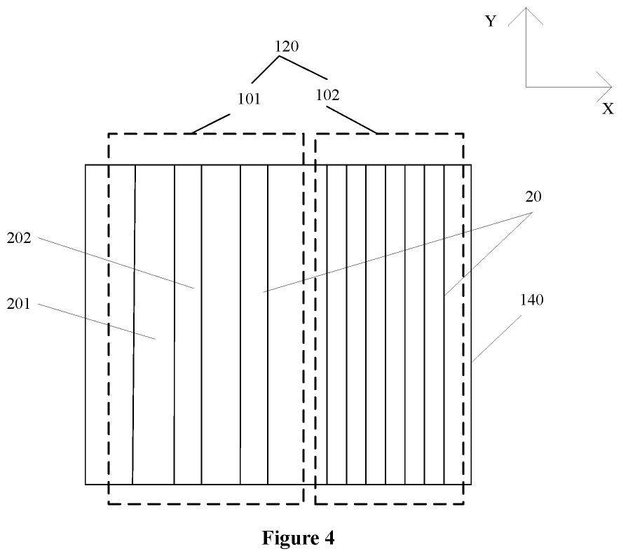

For example, as illustrated in FIG. 4, there is a first interval 201 or a second interval 202 between adjacent first wires 20 in the first division 101 included in the first wiring region 120 on the second surface 140 of the display panel. An average width, of the first interval 201 and the second interval 202 in the first division 101, in the first direction X is greater than a distance, between adjacent first wires 20 in the second division 102, in the first direction X. The multiple first wires are parallel to each other. The first interval 201 alternates with the second interval 202. Regions of the first wires 20 are hollows formed by patterning a dry film. In this way, distances between the first wires 20 in the first division 101 are even, to enhance the reliability of the patterned dry film formed by the first wires 20, to avoid damage to part of the dry film during removal of the dry film resulted from uneven adhesion of different parts of the dry film due to an excessive or insufficient interval between some of the first wires 20.

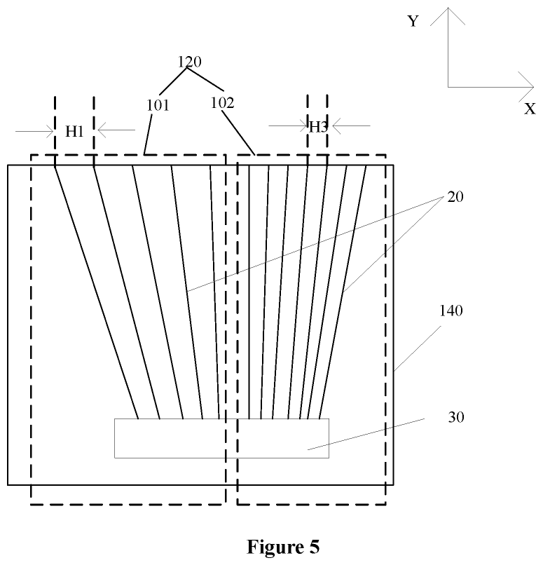

For example, as illustrated in FIG. 5, the display panel includes a drive chip 30 arranged on the second surface 140. Multiple first wires 20 are arranged along the first direction X and extend along the second direction Y. The first wire 20 has a first end and a second end in the second direction Y. The first end is close to the edge of the second surface 140, and the second end is electrically connected to the drive chip 30. A distance between ends of adjacent the first wires 20 in the first division 101 is H₁, and a distance between ends of the adjacent first wires 20 in the second division 102 is H₃. H₃ is less than H₁.

In the above embodiment, as illustrated in FIG. 5, the first wires 20 in the first wiring region 120 on the second surface 140 of the display panel are arranged along the first direction X and extend along the second direction Y. The first wire 20 has the first end and the second end. The first end is connected to the edge of the second surface, and the second end is electrically connected to the drive chip 30 arranged on the second surface 140. There are multiple distances between first ends of adjacent first wires 20 and multiple distances between second ends of adjacent first wires 20. A distance between ends of the adjacent first wires 20 in the first division 101 is H₁, and a distance between ends of the adjacent first wires 20 in the second division 102 is H₃. H₃ is less than H₁. The distance H₁ between ends of adjacent first wires 20 in the first division 101 is increased to be greater than the distance H₃ between ends of adjacent first wires 20 in the second division 102, where H₃ is less than or equal to H₂. Regions of the first wires 20 are hollows formed by patterning a dry film. In this way, an area of the patterned dry film formed adjacent first wires 20 is increased, to enhance the adhesion of the patterned dry film in the first division 101, and the patterned dry film in the first division 101 is not prone to be damaged during removal of the supporting film.

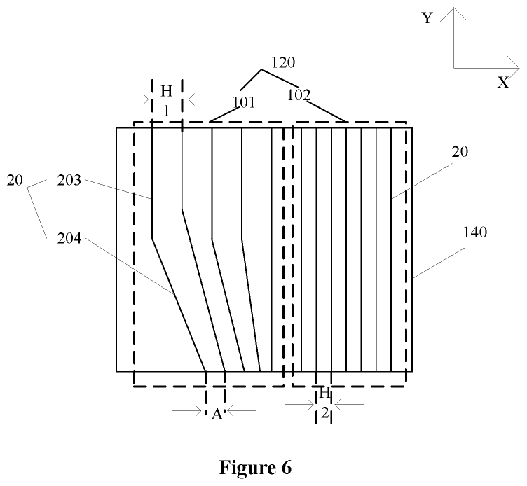

In some embodiments, as illustrated in FIG. 6, the first wire 20 in the first division 101 includes a first segment 203 and a second segment 204 that are connected. A distance between at least two adjacent first segments 203 is H₁, and a distance between any two adjacent second segments 204 is greater than or equal to H₂.

In the above embodiment, as illustrated in FIG. 6, first segments 203 of multiple first wires 20 in the first wiring region 120 on the second surface 140 are parallel to each other, and multiple second segments 204 of the multiple first wires 20 are not parallel. The multiple first wires 20 are arranged along the first direction X and extend along the second direction Y.

For example, as illustrated in FIG. 6, the first wire 20 in the first division 101 on the second surface 140 includes the first segment 203 and the second segment 204. A distance between adjacent first segments 203 is equal to the maximum distance H₁ between adjacent first wires 20 in the first division 101. A distance between any adjacent second segments 204 is A. A distance between adjacent first wires 20 in the second division 102 is H₂, and A is greater than or equal to H₂.

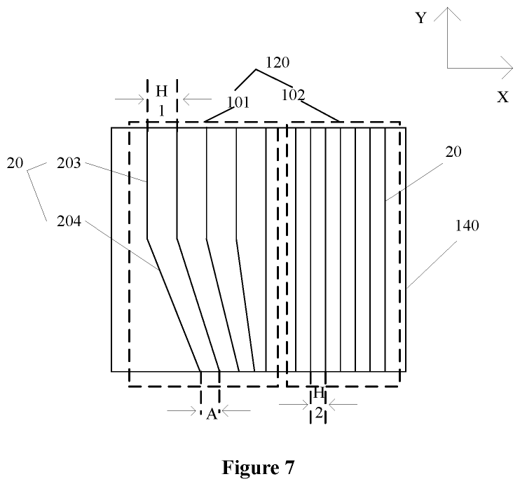

For example, as illustrated in FIG. 7, the first wire 20 in the first division 101 on the second surface 140 includes a first segment 203 and a second segment 204. A distance between adjacent first segments 203 is equal to the maximum distance H₁ between adjacent first wires 20 in the first division 101. A distance between any adjacent second segments 204 is A. A distance between adjacent first wires 20 in the second division 102 is H₂, and A is greater than or equal to H₂. Multiple first segments 203 arranged in the first division 101 are the equal in length. The first wires 20 are arranged along the first direction X and extend along the second direction Y.

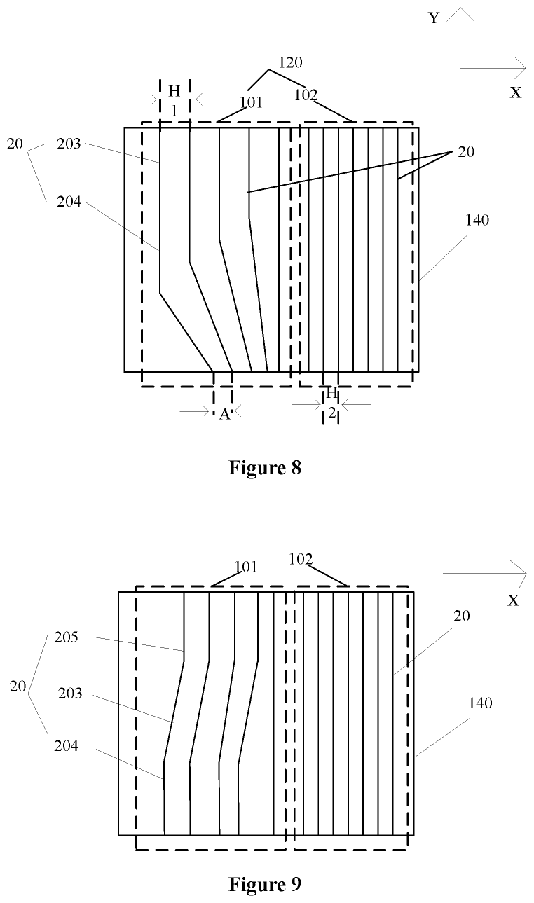

For example, as illustrated in FIG. 8, the first wire 20 in the first division 101 on the second surface 140 includes a first segment 203 and a second segment 204. A distance between adjacent first segments 203 is equal to the maximum distance H₁ between adjacent first wires 20 in the first division 101. A distance between any adjacent second segments 204 is A. A distance between adjacent first wires 20 in the second division 102 is H₂, and A is greater than or equal to H₂. The multiple first wires 20 are arranged along the first direction X. Lengths of the multiple first segments 203 are in descending order along the first direction X. The first wires 20 are arranged along the first direction X and extend along the second direction Y.

In the above embodiments, the distance between second segments 204 of adjacent first wires 20 is increased on a premise of ensuring that the distance H₁ between at least two adjacent first segments 203 in the first division 101 is greater than or equal to the distance H₂ between any two adjacent second segments 204, and A is greater than or equal to H₂, further increasing the area of the patterned dry film that is formed by the first wires 20 in the first division 101 and attached to the display panel. Regions of the first wires 20 are hollows formed by patterning the dry film.

In some embodiments, as illustrated in FIG. 9, the first wire 20 in the first division 101 includes a first segment 203. First segments 203 of multiple first wires 20 are arranged along the first direction X. The first segments 203 are inclined relative to the first wires 20 in the second division 102.

In the above embodiments, as illustrated in FIG. 9, the first wire 20 in the first division 101 on the second surface 140 of the display panel includes the first segment 203. Multiple first segments 203 in the first division 101 are arranged along the first direction X. The first segments 203 are not parallel to the first wires 20 in the second division 102.

In some embodiments, as illustrated in FIG. 9, the first segment 203 has a first side and a second side that are opposite to each other along a direction in which the first segment 203 extends. Along a direction from the first side to the second side, the first segment 203 in the first division 101 is inclined away from the first wires 20 in the second division 102.

In the above embodiment, as illustrated in FIG. 9, the first side of the first segment 203 is closer to the first wires 20 in the second division 102 than the second side of the first segment 203. The second side of the first segment 203 is closer to the edge of the first division 101 than the first side of the first segment 203.

In some embodiments, as illustrated in FIG. 9, the two sides of the first segment 203 are connected to a second segment 204 and a third segment 205 respectively. Distances each of which is between two adjacent third segments 205 are equal. Not all distances each of which is between two adjacent second segments 204 are equal.

In the above embodiments, as illustrated in FIG. 9, the first wire 20 in the first division 101 on the second surface 140 of the display panel further includes the second segment 204 and the third segment 205. The second segment 204 and the third segment 205 are connected to two sides of the first segment 203 respectively. In addition, distances each of which is between two adjacent third segments 205 are equal, and not all distances each of which is between two adjacent second segments 204 are equal. As illustrated in FIG. 9, along the first direction X, a distance between a first second segment 204 and a second segment 204 is equal to a distance between the second segment 204 and a third second segment 204, and the distance between the first second segment 204 and the second segment 204 is not equal to a distance between the third second segment 204 and a fourth second segment 204.

For example, as illustrated in FIG. 9, the first wire 20 in the first division 101 includes the first segment 203. First segments 203 of the multiple first wires 20 are arranged along the first direction X. The first segments 203 are inclined relative to the first wires 20 in the second divisions. The first segment 203 has the first side and the second side that are opposite to each other along the direction in which the first segment 203 extends. Along the direction from the first side to the second side, the first segment 203 in the first division 101 is inclined away from the first wires 20 in the second division 102. Two sides of the first segment 203 are connected to the second segment 204 and the third segment 205, respectively. Distances each of which is between two adjacent third segments 205 are equal, and not all distances each of which is between two adjacent second segments 204 are equal. Regions of the first wires 20 are hollows formed by patterning a dry film, and a minimum distance between adjacent first segments 203, a minimum distance between adjacent second segments 204, and a minimum distance between adjacent third segments 205 are greater than H₂ and an average distance between adjacent first wires 20 is increased, to increase an area of the attached patterned dry film formed adjacent first wires 20, to enhance the adhesion of the patterned dry film.

In some embodiments, as illustrated in FIG. 9, the multiple third segments 205 are parallel to each other, and the multiple second segments 204 are parallel to each other.

For example, as illustrated in FIG. 9, the first wire 20 in the first division 101 includes the first segment 203. First segments 203 of the multiple first wires 20 are arranged along the first direction X. The first segments 203 are inclined relative to the first wires 20 in the second divisions. The first segment 203 has the first side and the second side that are opposite to each other along the direction in which the first segment 203 extends. Along the direction from the first side to the second side, the first segment 203 in the first division 101 is inclined away from the first wires 20 in the second division 102. Two sides of the first segment 203 are connected to the second segment 204 and the third segment 205, respectively. Distances each of which is between two adjacent third segments 205 are equal, and not all distanced each of which is between two adjacent second segments 204 are equal. The multiple third segments 205 are parallel to each other, and the multiple second segments 204 are parallel to each other. Regions of the first wires 20 are hollows formed by patterning a dry film, and a minimum distance between adjacent first segments 203, a minimum distance between adjacent second segments 204, and a minimum distance between adjacent third segments 205 are greater than H₂ and an average distance between adjacent first wires 20 is increased, to increase an area of the attached patterned dry film formed by adjacent first wires 20. In addition, areas of intervals, between adjacent first wires 20, forming the patterned dry film are even, to enhance the adhesion and the reliability of the patterned dry film, to avoid damage to part of the dry film during removal of the dry film resulted from uneven adhesion of different parts of the dry film due to an excessive or insufficient interval between some of the first wires 20.

In some embodiments, as illustrated in FIG. 1 to FIG. 9, the multiple first wires in the second division 102 are arranged in parallel.

In the above embodiments, as illustrated in FIG. 1 to FIG. 9, the multiple first wires 20 in the second division 102 on the second surface 140 of the substrate 10 are parallel to each other and are arranged along the first direction X.

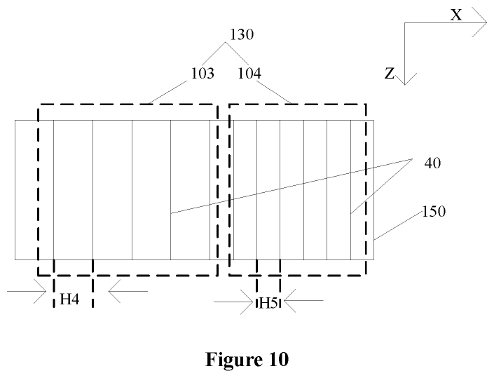

In some embodiments, as illustrated in FIG. 1, FIG. 2 and FIG. 10, the multiple first wires 20 are arranged along the first direction X, and the substrate 10 has side surfaces 150 connecting the first surface 110 and the second surface 140. At least one of the side surfaces 150 includes a second wiring region 130. The second wiring region 130 includes a third division 103 and a fourth division 104 that are arranged along the first direction X. A maximum distance between any two adjacent second wires 40 in the third division 103 is H₄, and a maximum distance between any two adjacent second wires 40 in the fourth division 104 is H₅. H₄ is greater than or equal to H₅.

In the above embodiment, as illustrated in FIG. 1, FIG. 2 and FIG. 10, the substrate 10 of the display panel further has multiple side surfaces 150 connecting the first surface 110 and the second surface 140. At least one of the side surfaces 150 includes the second wiring region 130. The second wiring region 130 includes the third division 103 and the fourth division 104. The third division 103 and the fourth division 104 are arranged along the first direction X. The first direction X is the direction along which the first wires 20 on the second surface are arranged. The maximum distance between any two adjacent second wires in the third division 103 is H₄, the maximum distance between any two adjacent second wires 40 in the fourth division 104 is H₅, and H₄ is greater than or equal to H₅. Regions of the second wires 40 are hollows formed by patterning a dry film. On a premise of increasing the distance between adjacent first wires 20 in the first division 101 on the back surface of the display panel, the distance between adjacent second wires 40 in the third division 103 on the side surface 150 of the display panel is not less than the distance between adjacent second wires 40 in the fourth division 104, to increase an area of the patterned dry film that is formed by the second wires 40 in the third division 103 connected to the first division 101 and is attached to the display panel, to enhance the adhesion of the patterned dry film formed by adjacent second wires 40 on the side surface 150.

In the above embodiment, as illustrated in FIG. 2, the side surface 150 of the substrate 10 of the display panel may be provided with the second wires 40 and protective adhesive 114. Functional layers can be arranged on the side surface of the display panel properly according to actual situations, which is not limited in the present disclosure. In a case that another layer is arranged on the side surface 150, the second wires 40 on the side surface 150 are not in direct contact with the substrate.

In some embodiments, as illustrated in FIG. 10, the second wires 40 extend along the third direction Z. The third direction Z intersects with the first direction X.

In the above embodiments, as illustrated in FIG. 2 and FIG. 10, the second wires on the side surface 150 of the display panel are arranged along the first direction X and extend along the third direction Z. The third direction Z intersects with the first direction X. The present disclosure is not limited to a case that the third direction Z is perpendicular to the first direction X as illustrated in FIG. 10 as long as the third direction Z intersects with the first direction X.

In some embodiments, as illustrated in FIG. 10, the third division 103 and the fourth division 104 are arranged along the first direction X.

In the above embodiment, as illustrated in FIG. 10, the third division 103 and the fourth division 104 on the side surface 150 of the display panel are arranged along the first direction X within the second wiring region 130. The third division 103 is arranged close to the edge of the second wiring region 130, and the fourth division 104 is arranged close to the center of the second wiring region 130.

For example, as illustrated in FIG. 1, FIG. 2 and FIG. 10, the back surface, i.e., the second surface 140, of the display panel includes the first division 101 and the second division 102. The distance between adjacent first wires 20 in the first division 101 is H₁, the distance between adjacent first wires 20 in the second division 102 is H₂, and H₁ is greater than H₂. The maximum distance between any two adjacent second wires 40 in the third division 103 on the side surface 150 of the display panel is H₄, the maximum distance between any two adjacent second wires 40 in the fourth division 104 is H₅, and H₄ is greater than or equal to H₅. The regions of the second wires 40 are hollows formed by patterning the dry film. On a premise of setting the distance between adjacent second wires 40 in the third division 103 on the side surface 150 of the display panel to be not less than the distance between adjacent second wires 40 in the fourth division 104 on the side surface 150 of the display panel, the distance between adjacent second wires 40 in the third division 103 on the back surface of the display panel is increased, and an area of the patterned dry film that is formed by second wires 40 in the third division 103 and attached to the display panel is increased, to enhance the adhesion of the patterned dry film formed by the second wires 40 on the side surface 150.

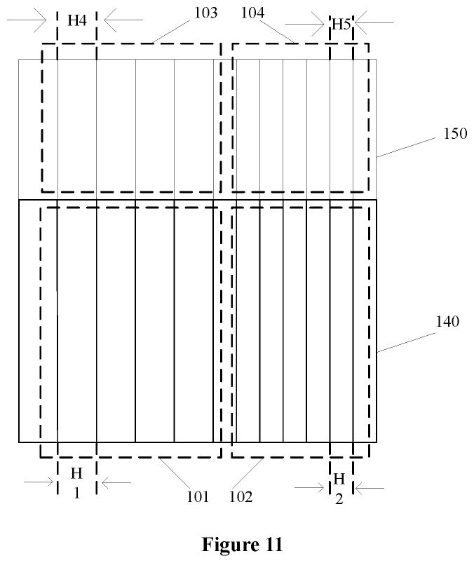

In some embodiments, as illustrated in FIG. 1, FIG. 2 and FIG. 11, the first division 101 is connected to the third division 103, and the second division 102 is connected to the fourth division 104.

In the above embodiment, as illustrated in FIG. 1, FIG. 2 and FIG. 11, in a case of spreading the side surface 150 and the second surface 140 (the back surface) of the display panel, the first division 101 on the second surface 140 of the display panel is arranged corresponding to the third division 103 on the side surface 150 of the display panel, and the first wires 20 arranged in the first division 101 are connected to the second wires 40 arranged in the third division 103 respectively. The second division 102 on the second surface 140 of the display panel is arranged corresponding to the fourth division 104 on the side surface 150 of the display panel, and the first wires 20 in the second division 102 are connected to the second wires 40 in the fourth division 104 respectively.

For example, as illustrated in FIG. 2 and FIG. 11, H₄ is equal to H₁. The back surface, i.e., the second surface 140, of the display panel includes the first division 101 and the second division 102. A distance between adjacent first wires 20 in the first division 101 is H₁, a distance between adjacent first wires 20 in the second division 102 is H₂, and H₁ is greater than H₂. A maximum distance between any two adjacent second wires 40 in the third division 103 on the side surface 150 of the display panel is H₁, and a maximum distance between any two adjacent second wires 40 in the fourth division 104 is H₁. H₁ is greater than or equal to H₅.

In the above embodiment, both the distance between adjacent second wires 40 in the third division 103 and the distance between adjacent second wires 40 in the fourth division 104 are be equal to the maximum distance H₁ between adjacent first wires 20 in the first division 101. Regions of the second wires 40 are hollows formed by patterning a dry film, and an area of the patterned dry film formed by adjacent second wires 40 in the third division 103 is increased, to enhance the adhesion of the patterned dry film formed by adjacent second wires 40 on the side surface 150, and the dry film is not prone to be damaged during removal of the supporting film.

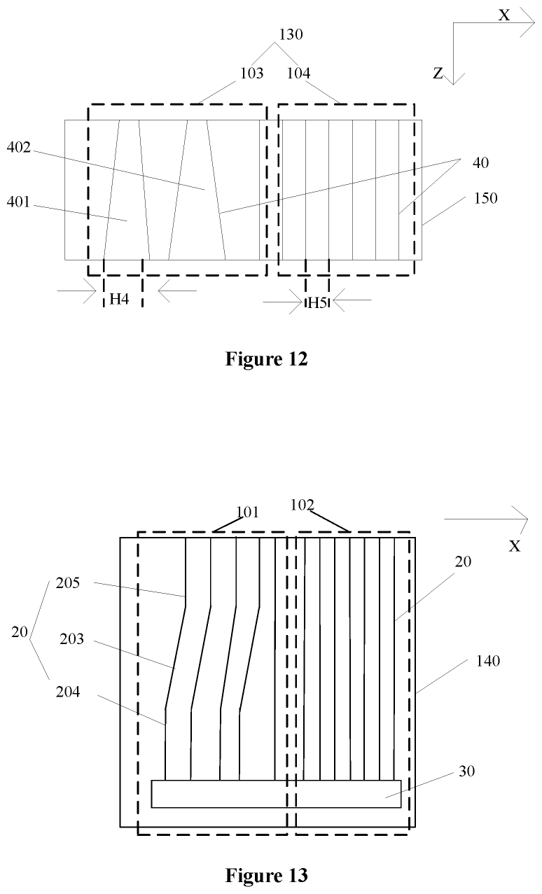

In some embodiments, as illustrated in FIG. 12, there is a third interval 401 or a fourth interval 402 between adjacent second wires 40 in the third division 103. The third interval 401 alternates with the fourth interval 402 along the first direction X. The third interval 401 tapers against the third direction Z, and the fourth interval 402 tapers along the third direction Z. The third direction Z intersects with the first direction X.

In the above embodiment, as illustrated in FIG. 12, there is the third interval 401 or the fourth interval 402 between adjacent second wires 40 in the second wiring region 130 on the side surface 150 of the display panel. The third interval 401 and the fourth interval 402 are arranged along the first direction X in the second wiring region 130. The third interval 401 tapers against the third direction Z, and the fourth interval 402 tapers along the third direction Z. The third direction Z intersects with the first direction X. The present disclosure is not limited to a case that the third direction Z is perpendicular to the first direction X as illustrated in FIG. 12.

In some embodiments, as illustrated in FIG. 2, FIG. 10 and FIG. 13, the display panel includes the drive chip 30 or a drive module arranged on the second surface 140. The substrate 10 has side surfaces 150 connecting the first surface 110 and the second surface 140. The third segments 205 pass through the side surface 150 and extend to the second surface 140. The second segments 204 are electrically connected to the drive chip 30 or the drive module.

For example, as illustrated in FIG. 2, FIG. 10 and FIG. 13, the first wires 20 in the first division 101 of the display panel each include the first segment 203. The first segments 203 of the multiple first wires 20 are arranged along the first direction X. The first segments 203 are inclined relative to the first wires 20 in the second division 102. The first segment 203 has the first side and the second side that are opposite to each other along the direction in which the first segment 203 extends. The first segments 203 are equally spaced on first sides of the first segments 203. Along the direction from the first side to the second side, the first segment 203 in the first division 101 is inclined away from the first wires 20 in the second division 102. Two sides of the first segment 203 are connected to the second segment 204 and the third segment 205, respectively. Distances each of which is between two adjacent third segments 205 are equal, and not all distances each of which is between two adjacent second segments 204 are equal. The display panel includes the drive chip 30 or the drive module arranged on the second surface 140. The substrate 10 has the side surfaces 150 connecting the first surface 110 and the second surface 140. The third segments 205 pass through the side surface 150 and extend to the second surface 140. The second segments 204 are electrically connected to the drive chip 30 or the drive module. Regions of the first wires are hollows formed by patterning the dry film. On a premise of setting the distance between adjacent second wires 40 in the third division 103 on the side surface 150 to be not less than the distance between adjacent second wires 40 in the fourth division 104, the distance between adjacent first segments 203, the distance between adjacent second segments 204, and the distance between adjacent third segments 205 of adjacent first wires 20 in the first division 101 on the back surface of the display panel are increased, and the area of the patterned dry film that is formed by the first wires 20 in the first division 101 and attached to the display panel is increased, to enhance the adhesion of the patterned dry film between adjacent first wires 20 in the first division 101.

In the above embodiment, as illustrated in FIG. 13, the second segments 204 in the first division 101 of the display panel are electrically connected to the drive chip 30 or the drive module on the second surface of the display panel. As illustrated in FIG. 10, the second wire 40 in the third division 103 on the side surface is part of the third segment 205, and the third segment 205 extends to the second surface passing through the side surface.

In some embodiments, the first surface is provided with a signal bonding region, a multiplexer, and a drive circuit. The multiplexer is electrically connected to the signal bonding region and is configured to receive a display control signal transmitted from the signal bonding region. The drive circuit is electrically connected to the multiplexer, and is configured to receive the display control signal and control brightness and color of pixels in the active area of the display panel in response to the display control signal.

In the above embodiment, the first surface is arranged in the display face of the display panel. The first surface is provided with the signal bonding region, the multiplexer, and the drive circuit. The multiplexer is electrically connected to the signal bonding region, and is configured to receive the display control signal transmitted from the signal bonding region. The drive circuit is electrically connected to the multiplexer, and is configured to receive the display control signal and control the brightness and the color of the pixels in the active area of the display panel in response to the display control signal. The active area of the display panel may further be provided with other functional devices or functional regions, which is not limited in the present disclosure.

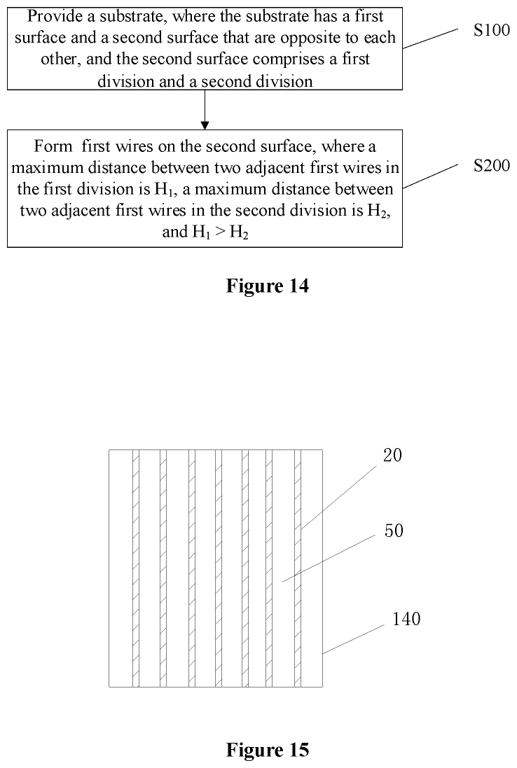

A method for manufacturing a display panel is further provided according to an embodiment of the present disclosure. As illustrated in FIG. 14, the method includes the following steps S100 and S200.

In step S100, a substrate is provided. The substrate has a first surface and a second surface that are opposite to each other, and the second surface includes a first division and a second division.

In step S200, multiple first wires are formed on the second surface. A maximum distance H₁ between two adjacent first wires in the first division is greater than a maximum distance H₂ between two adjacent first wires in the second division.

In the display panel manufactured with the method described above, the second surface, of the substrate, away from the display face of the display panel includes the first division and the second division. The distance between adjacent first wires in the first division is greater than the distance between adjacent first wires in the second division, to increase an area of the patterned dry film that is formed by the first wires in the first division and attached to the display panel, to reduce a risk of detachment of the patterned dry film during removal of a supporting film, to improve a product yield.

As illustrated in FIG. 15, a top view of part of the second surface 140 of the display panel is taken as an example. Before the dry film is removed, intervals between adjacent first wires 20 on the second surface 140 form a dry film 50, and the first wires 20 are patterns in the dry film 50. A shape of the first wire 20 depends on actual situations.

Exemplary embodiments of the method for manufacturing the display panel according to the present disclosure are described in detail below in conjunction with the drawings. However, the exemplary embodiments may be implemented in various forms, and should not be construed as being limited to the embodiments illustrated herein. It should be understood that these embodiments are described to cause the present disclosure to be thorough and complete, and convey a full concept of the exemplary embodiments.

First, step S100 is performed. That is, the substrate is provided. The substrate has the first surface and the second surface that are opposite to each other, and the second surface includes the first division and the second division.

A substrate having a first surface and a second surface that are opposite to each other is provided. The second surface includes a first division and a second division. The first surface is arranged close to an active area of the display panel, and the second surface is arranged away from the active area of the display panel.

After the step of providing the substrate, step S200 is performed. That is, multiple first wires are formed on the second surface. A maximum distance H₁ between two adjacent first wires in the first division is greater than a maximum distance H₂ between two adjacent first wires in the second division.

The multiple first wires are formed on the second surface of the substrate provided in step S100. The maximum distance between two adjacent first wires in the first division is H₁, and the maximum distance between two adjacent first wires in the second division is H₂. H₁ is greater than H₂. In this way, an area of the patterned dry film formed by adjacent first wires in the first division on the second surface is increased, to reduce a risk of detachment of the patterned dry film during removal of a supporting film, to improve a yield of products.

In some embodiments, the first wires are formed on the second surface by performing the following steps S110 and S210.

In step S110, a first mask layer is formed in a first wiring region on the second surface of the substrate.

The first wiring region on the second surface of the substrate is coated with a photoresist layer to form the first mask layer.

In step S210, the first mask layer is etched to form multiple first hollows in the first mask layer. The multiple first hollows are arranged along a first direction and extend along a second direction. The second direction intersects with the first direction. There is a first interval or a second interval between adjacent first hollows in the first division. The first interval alternates with the second interval in the first direction. The first intervals each taper along the second direction, and the second intervals each taper against the second direction. The first wires are formed among the first hollows.

Steps such as exposure and development are performed on the first mask layer formed in step S110 to form the multiple first hollows, and there is the first interval or the second interval between adjacent first hollows in the first division. The first interval alternates with the second interval in the first direction. The first intervals each taper along the second direction, and the second intervals each taper against the second direction. The first hollows correspond to the first wires.

With the method for manufacturing a display panel, the first hollows and the second hollows are formed by performing photolithography on the dry film made of photoresist. Then, the dry film is peeled off the rigid substrate, and is attached to the side surfaces and the second surface of the display panel through 3D adhesion. A metal film is applied and then is peeled off. In this way, the first wires and the second wires are formed, and drive wires on the first surface of the substrate of the display panel extend to the second surface. The dry film is covered with a supporting film. In the manufactured display panel, an area of the dry film formed by the first interval and the second interval between adjacent first hollows in the first division is greater than an area of the dry film formed between adjacent first hollows in the second division, and a risk of detachment of the patterned dry film attached to the second surface of the substrate of the display panel during removal of the supporting film is reduced, to improve a product yield.

In some embodiments, the first wires are formed on the second surface by performing the following steps S120 and S220.

In step S120, a first mask layer is formed in the first wiring region on the second surface of the substrate.

The first wiring region on the second surface of the substrate is coated with a photoresist layer to form the first mask layer.

In step S220, the first mask layer is etched to form multiple first hollows in the first mask layer. A distance between ends of the adjacent first hollows in the first division is H₁, and a distance between ends of the adjacent first hollows in the second division is H₃. H₃ is less than H₁. The first wires are formed among the first hollows.

Steps such as exposure and development are performed on the first mask layer formed in step S110 to form the multiple first hollows. A distance between ends of the adjacent first hollows in the first division is H₁, and a distance between ends of the adjacent first hollows in the second division is H₃. H₃ is less than H₁. The first hollows correspond to the first wires.

In the display panel manufactured with the method described above, an area of the dry film formed between adjacent first hollows in the first division is greater than an area of the dry film formed between adjacent first hollows in the second division to enhance the adhesion of the patterned dry film in the first division, and the patterned dry film in the first division is not prone to be damaged during removal of the supporting film.

In some embodiments, the display panel has side surfaces connecting the first surface and the second surface, and at least one of the side surfaces includes a second wiring region. The second wiring region includes a third division and a fourth division that are arranged along the first direction. The second wires are formed on the side surface by performing the following steps S300 and S400.

In step S300, a second mask layer is formed in the second wiring region.

The second wiring region on the side surface of the substrate is coated with a photoresist layer to form the second mask layer.

In step S400, the second mask layer is etched to form multiple second hollows arranged along the first direction in the second mask layer. A maximum distance between any two adjacent second hollows in the third division is H₄, and a maximum distance between any two adjacent second hollows in the fourth division is H₅. H₄ is greater than or equal to H₅. The second wires are formed among the second hollows.

Steps such as exposure and development are performed on the second mask layer formed in step S300 to form the multiple second hollows, and the second hollows are arranged along the first direction. A maximum distance between any two adjacent second hollows in the third division is H₄, a maximum distance between any two adjacent second hollows in the fourth division is H₅, and H₄ is greater than or equal to H₅. The second wires are formed among the second hollows.

In the above embodiment, the first mask layer and the second mask layer each are a dry film, and the region after removal of the dry films includes regions between adjacent first wires and regions between adjacent second wires.

In the display panel manufactured with the method described above, on a premise that the area of the dry film formed between adjacent first hollows in the first division is greater than the area of the dry film formed between adjacent first hollows in the second division, an area of the dry film formed between adjacent second hollows in the third division is greater than or equal to an area of the dry film formed between adjacent first hollows in the fourth division, further reducing the risk of detachment of the patterned dry film on the side surface during removal of the supporting film.

A display screen is further provided according to an embodiment of the present disclosure. The display screen includes the display panel described above, or a display panel manufactured with the method described above.

A display device is further provided according to an embodiment of the present disclosure. The display device includes the display screen described above.

A tiled display apparatus is further provided according to an embodiment of the present disclosure. The tiled display apparatus includes multiple of the display device described above.

It should be noted that the terms “comprise”, “include”, or any other variants thereof are intended to encompass a non-exclusive inclusion, and a process, method, article, or device including a series of elements includes not only those elements but also elements that are not explicitly listed, or elements that are inherent to such process, method, article, or device. Unless expressively limited otherwise, the statement “comprising (including) a . . . ” does not exclude the case that other identical elements exist in the process, method, product or device.

The embodiments of the present disclosure are described above and the embodiments are not intended to limit the present disclosure. Various modifications and variations to the present disclosure. Any modifications, equivalent substitutions, improvements and the like made within the spirit and the principle of the present disclosure fall within the scope of the claims of the present disclosure.

1. A display panel, comprising:
a substrate, comprising a first surface and a second surface that are opposite to each other; and
a plurality of first wires, arranged on a side of the first surface away from the second surface, wherein the first surface faces a display face of the display panel, the second surface comprises a first division and a second division, a maximum distance between two adjacent first wires in the first division is H₁, a maximum distance between two adjacent first wires in the second division is H₂, and H₁ is greater than H₂.

2. The display panel according to claim 1, wherein
the plurality of first wires are arranged along a first direction and extend along a second direction, and the second direction intersects with the first direction.

3. The display panel according to claim 1, wherein
the plurality of first wires are arranged along the first direction, and the first division and the second division are arranged along the first direction.

4. The display panel according to claim 1, wherein
a first wiring region is arranged on the second surface and comprises the first division and the second division, and the first division is arranged on a side of the second division close to an edge of the first wiring region.

5. The display panel according to claim 1, wherein
a distance between ends of the adjacent first wires in the first division is H₁.

6. The display panel according to claim 5, wherein
a distance between ends of the adjacent first wires in the second division is H₃, and H₃ is less than H₁.

7. The display panel according to claim 5, further comprising:
a drive chip arranged on the second surface, wherein the plurality of first wires are arranged along the first direction and extend along the second direction, the plurality of first wires are provided with first ends and second ends in the second direction, the first ends are close to an edge of the second surface, and the second ends are electrically connected to the drive chip.

8. The display panel according to claim 2, wherein
the first wires in the first division are arranged at first intervals or at second intervals, the first intervals alternate with the second intervals in the first direction, the first intervals taper along the second direction, and the second intervals taper against the second direction.

9. The display panel according to claim 1, wherein
the plurality of first wires in the first division comprise a plurality of first segments and a plurality of second segments that are connected respectively, a distance between at least two adjacent first segments is equal to H₁, and a distance between two adjacent second segments is greater than or equal to H₂.

10. The display panel according to claim 1, wherein
the plurality of first segments are equal in length; or
the plurality of first segments are arranged along the first direction, and respective lengths of the plurality of first segments are in descending order along the first direction.

11. The display panel according to claim 1, wherein the plurality of first wires are arranged along a first direction, the substrate comprises side surfaces connecting the first surface and the second surface, at least one of the side surfaces comprises a second wiring region comprising a third division and a fourth division that are arranged along the first direction, a maximum distance between adjacent second wires in the third division is H₄, a maximum distance between adjacent second wires in the fourth division is H₅, and H₄ is greater than or equal to H₅.

12. The display panel according to claim 11, wherein
the first division is connected to the third division, and the second division is connected to the fourth division.

13. The display panel according to claim 11, wherein
the second wires extend along a third direction, and the third direction intersects with the first direction.

14. The display panel according to claim 11, wherein
H₄ is equal to H₁.

15. The display panel according to claim 11, wherein
the second wires in the third division are at third intervals or fourth intervals, the third intervals alternate with the fourth intervals in the first direction, the third intervals taper against a third direction, the fourth intervals taper along the third direction, and the third direction intersects with the first direction.

16. The display panel according to claim 1, wherein
the first wires in the first division comprise first segments, the first segments are arranged along the first direction, and the first segments are inclined relative to the first wires in the second division.

17. The display panel according to claim 16, wherein
a first segment has a first side and a second side that are opposite to each other along a direction in which the first segment extends; and
along a direction from the first side to the second side, the first segments are inclined away from the first wires in the second division.

18. The display panel according to claim 17, wherein
The first segments are connected to second segments and third segments at both sides respectively, the third segments are arranged at equal intervals and second segments are arranged at unequal intervals.

19. The display panel according to claim 18, wherein
the third segments n are parallel and the second segments comprised are parallel.

20. The display panel according to claim 18, further comprising:
a drive chip or a drive module arranged on the second surface, wherein the substrate comprises a side surface connecting the first surface and the second surface, the third segments extend to the second surface through the side surface, and the second segments are electrically connected to the drive chip or the drive module.

21. The display panel according to claim 1, wherein
the plurality of first wires in the second division are parallel.

22. The display panel according to claim 1, wherein the first surface is provided with:
a signal bonding region;
a multiplexer, electrically connected to the signal bonding region and configured to receive a display control signal transmitted from the signal bonding region; and
a drive circuit, electrically connected to the multiplexer and configured to receive the display control signal and control brightness and colors of pixels in an active area of the display panel in response to the display control signal.

23. A method for manufacturing a display panel, comprising:
providing a substrate, wherein the substrate has a first surface and a second surface that are opposite to each other, and the second surface comprises a first division and a second division; and
forming a plurality of first wires on the second surface, wherein a maximum distance between two adjacent first wires in the first division is H₁, a maximum distance between two adjacent first wires in the second division is H₂, and H₁ is greater than H₂.

24. The method according to claim 23, wherein the forming the plurality of first wires on the second surface comprises:
forming a first mask layer in a first wiring region on the second surface of the substrate;
etching the first mask layer to form a plurality of first hollows in the first mask layer, wherein a distance between ends of adjacent first hollows in the first division is H₁, a distance between ends of first adjacent hollows in the second division is H₃, and H₃ is less than H₁; and
forming the plurality of first wires among the plurality of first hollows.

25. The method according to claim 23, wherein the forming the plurality of first wires on the second surface comprises:
forming a first mask layer in the first wiring region on the second surface of the substrate;
etching the first mask layer to form a plurality of first hollows in the first mask layer, wherein the plurality of first hollows are arranged along a first direction and extend along a second direction, the first direction intersects with the second direction, adjacent first hollows in the first division are arranged at first or second intervals, the first intervals alternate with the second intervals in the first direction, the first intervals taper along the second direction, and second intervals taper against the second direction; and
forming the plurality of first wires among the plurality of first hollows.

26. The method according to claim 23, wherein the display panel comprises side surfaces connecting the first surface and the second surface, at least one of the side surfaces comprises a second wiring region comprising a third division and a fourth division that are arranged along the first direction, and the method further comprises:
forming a second mask layer in the second wiring region;
etching the second mask layer to form a plurality of second hollows arranged along the first direction in the second mask layer, wherein a maximum distance between adjacent second hollows in the third division is H₄, a maximum distance between adjacent second hollows in the fourth division is H₅, and H₄ is greater than or equal to H₅; and
forming the plurality of second wires among the plurality of second hollows.

27. A display screen, comprising: a display panel, wherein
the display panel comprises:
a substrate, comprising a first surface and a second surface that are opposite to each other; and
a plurality of first wires, arranged on a side of the first surface away from the second surface, wherein the first surface faces a display face of the display panel, the second surface comprises a first division and a second division, a maximum distance between two adjacent first wires in the first division is H₁, a maximum distance between two adjacent first wires in the second division is H₂, and H₁ is greater than H₂; or
the display panel is manufactured by:
providing a substrate, wherein the substrate has a first surface and a second surface that are opposite to each other, and the second surface comprises a first division and a second division; and
forming a plurality of first wires on the second surface, wherein a maximum distance between two adjacent first wires in the first division is H₁, a maximum distance between two adjacent first wires in the second division is H₂, and H₁ is greater than H₂.

28. A display device, comprising the display screen according to claim 27.

29. A tiled display apparatus, comprising a plurality of the display devices according to claim 28.
